(19) United States
(12) Patent Application Publication
(10) Pub. No.: US 2015/0364657 A1
(43) Pub. Date: Dec. 17, 2015

(54) METHOD OF MANUFACTURING LIGHT-EMITTING DEVICE

(71) Applicant: TOYODA GOSEI CO., LTD., Kiyosu-shi (JP)

(72) Inventors: Takashi NONOGAWA, Kiyosu-shi (JP); Masakata KOSEKI, Kiyosu-shi (JP); Kosei FUKUI, Kiyosu-shi (JP); Toshimasa HAYASHI, Kiyosu-shi (JP)

(21) Appl. No.: 14/724,715

(22) Filed: May 28, 2015

(30) Foreign Application Priority Data
Jun. 13, 2014 (JP) 2014-122612

(51) Int. Cl. H01L 33/50; H01L 33/56

(52) U.S. Cl. CPC H01L 33/502; H01L 33/56

(57) ABSTRACT

A method of manufacturing a light-emitting device includes providing an LED chip mounted on a base substrate, and dripping a droplet of a phosphor-containing resin to cover the LED chip. The droplet is dot-printed on the base substrate and/or the LED chip by inkjet printing.

The present application is based on Japanese patent application No.2014-122612 filed on Jun. 13, 2014, the entire contents of which are incorporated herein by reference.

### BACKGROUND OF THE INVENTION

1. Field of the Invention

The invention relates to a method of manufacturing a light-emitting device.

2. Description of the Related Art

A light-emitting device is known in which a portion above an LED chip is covered with a phosphor-containing resin (see e.g. JP-A-2012-9905). In operating the light-emitting device, a color of light emitted from the LED chip and transmitting through the resin is mixed with a color of fluorescence produced by the phosphor in the resin so as to provide an emission color of the light-emitting device.

### SUMMARY OF THE INVENTION

It is an object of the invention to provide a method of manufacturing a light-emitting device that allows a phosphor-containing resin to have high heat release characteristics and thereby improves reliability thereof

(1) According to one embodiment of the invention, a method of manufacturing a light-emitting device comprises:

providing an LED chip mounted on a base substrate; and

dripping a droplet of a phosphor-containing resin to cover the LED chip,

wherein the droplet is dot-printed on the base substrate and/or the LED chip by inkjet printing.

In the above embodiment (1) of the invention, the following modifications and changes can be made.

(i) A concentration of a phosphor included in the phosphor-containing resin is not less than 20 vol %.

(ii) The droplet has a viscosity of not less than 5 Pa·s.

### Effects of the Invention

According to one embodiment of the invention, a method of manufacturing a light-emitting device can be provided that allows a phosphor-containing resin to have high heat release characteristics and thereby improves reliability thereof

### BRIEF DESCRIPTION OF THE DRAWINGS

Next, the present invention will be explained in more detail in conjunction with appended drawings, wherein:

FIG. 1 is a vertical cross-sectional view showing a light-emitting device in an embodiment;

FIG. 2 is a schematic view showing the light-emitting device and an inkjet head as a dispenser in the process of forming a phosphor-containing resin in the light-emitting device; and

FIG. 3 is an enlarged view showing the state in which the phosphor-containing resin is being dripped from the inkjet head.

### DETAILED DESCRIPTION OF THE PREFERRED EMBODIMENTS

### Embodiment

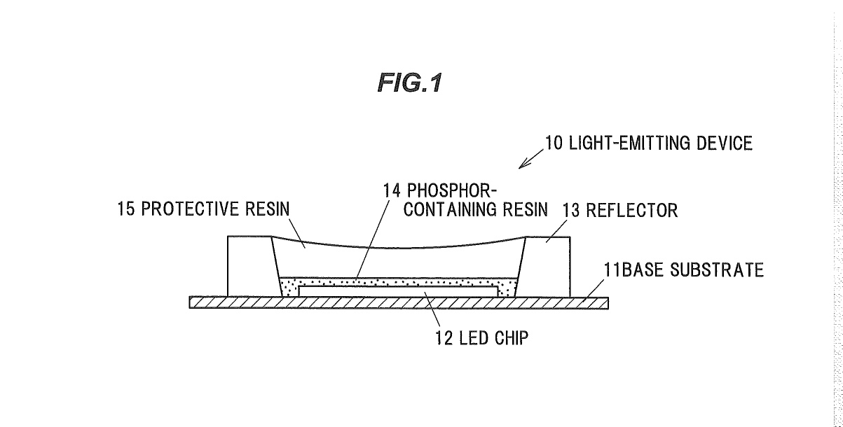

FIG. 1 is a vertical cross-sectional view showing a light-emitting device 10 in the embodiment. The light-emitting device 10 is a COB (Chip On Board) light-emitting device and has an LED chip 12 mounted on a plate-shaped base substrate 11, an annular reflector 13 surrounding the LED chip 12 on the base substrate 11, a phosphor-containing resin 14 covering the surface of the LED chip 12, and a protective resin 15 formed on the phosphor-containing resin 14.

The base substrate 11 is, e.g., a conductive substrate such as aluminum substrate, or a wiring board such as glass-epoxy substrate having a wiring on the surface thereof. The base substrate 11 has a conductive region at least on the surface thereof. The conductive region of the base substrate 11 is, e.g., the entire region in case of a conductive substrate and is a region with a wiring in case of a wiring board.

The LED chip 12 has, e.g., a chip substrate and a crystal layer which includes a light-emitting layer and cladding layers sandwiching the light-emitting layer. The LED chip 12 may be either a face-up LED chip with the crystal layer facing upward or a face-down LED chip with the crystal layer facing downward. The LED chip 12 is electrically connected to the conductive region of the base substrate 11 by wires or conductive bumps, etc.

The reflector 13 is formed of, e.g., a thermoplastic resin such as polyphthalamide resin, LCP (Liquid Crystal Polymer) or PCT (Polycyclohexylene Dimethylene Terephalate), a thermosetting resin such as silicone resin, modified silicone resin, epoxy resin or modified epoxy resin, or ceramics. The reflector 13 may contain light-reflecting particles of titanium dioxide, etc., to improve light reflectance.

The phosphor-containing resin 14 is a resin containing particulate phosphors. The resin constituting the phosphor-containing resin 14 is, e.g., a silicone-based resin or an epoxy-based resin. The type of the phosphor is not limited. For example, when emission color of the LED chip 12 is blue and fluorescence color of the phosphor contained in the phosphor-containing resin 14 is yellow, emission color of the light-emitting device 10 is white.

The phosphor-containing resin 14 in the present embodiment is formed by printing fine dots using inkjet technique and thus can contain a phosphor at a higher concentration than a typical drip molding (potting) method. Phosphors generally have higher thermal conductivity than resins. Therefore, the higher the concentration of the phosphor contained in the phosphor-containing resin 14, the higher the thermal conductivity of the phosphor-containing resin 14. For example, thermal conductivity of YAG phosphor is about 12 W/mk and that of a silicone resin is about 0.1 W/mk.

In order to effectively improve thermal conductivity of phosphor-containing resin 14, the concentration of the phosphor contained in the phosphor-containing resin 14 is preferably not less than 20 vol %. The maximum concentration at which the phosphor-containing resin 14 can be formed by inkjet dot printing (the concentration at which the phosphor-containing resin 14 can be dripped from an inkjet head as a dispenser) is the upper limit of the phosphor concentration, which is, e.g., about 40 vol %.

A resin for the phosphor-containing resin 14 is a low gas-permeable material and may be e.g. norbornene silicone, phenyl silicone or liquid glass with high crosslink density (siloxane, etc.). In this case, it is possible to prevent the conductive region of the base substrate 11 from discoloring when exposed to metal corroding gas such as sulfur-based gas.

The phosphor-containing resin 14 may contain a filler. As a filler having a high refractive index of not less than 1.5, it is possible to use powder of ITO, TiO₂, ZnO₂, ZrO₂, spin-on glass, titania-based composite oxide (TiMOx, M═Si, Fe, Zr, Sn, Sb, W, Ce), or YAG, etc. A diameter of the filler is, e.g., from several nm to several tens nm and a concentration of the filler is, e.g., 50 mass %. Similarly to phosphor, fillers generally have higher thermal conductivity than resins. Therefore, it is possible to improve thermal conductivity of the phosphor-containing resin 14 by adding a filler thereto.

The protective resin 15 is formed of, e.g., a resin material such as silicone-based resins or epoxy-based resins, or glass. The protective resin 15 does not contain phosphor. Alternatively, the light-emitting device 10 may not have the protective resin 15.

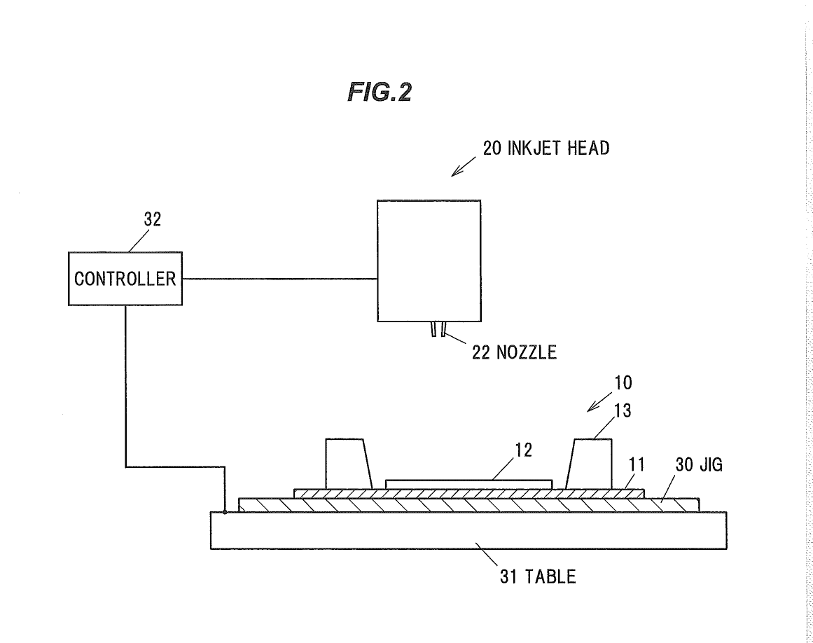

FIG. 2 is a schematic view showing the light-emitting device 10 and an inkjet head 20 as a dispenser in the process of forming the phosphor-containing resin 14.

In forming the phosphor-containing resin 14, the light-emitting device 10 is fixed to a jig 30 which is placed on a horizontally-movable table 31.

The inkjet head 20 has needle-shaped nozzles 22 as ink ejection ports. An ink-supply tube (not shown) is connected to the inkjet head 20. A controller 32 controls, e.g., a horizontal position of the inkjet head 20 and timing of ejecting the phosphor-containing resin 14.

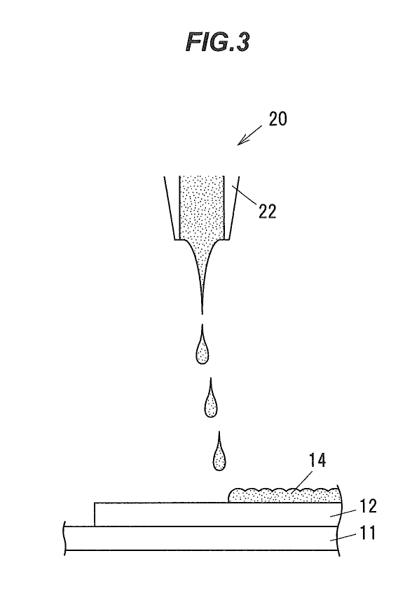

FIG. 3 is an enlarged view showing the state in which the phosphor-containing resin 14 is being dripped from the inkjet head 20.

When dripping the phosphor-containing resin 14 into the light-emitting device 10, an external force is instantaneously applied to the phosphor-containing resin 14 in the inkjet head 20. The external force applying means is different depending on the inkjet method and is, e.g., a thermal method, a piezo method and an electrostatic attraction method, etc. Then, at the moment which the external force is applied, the phosphor-containing resin 14 in the tip of the nozzle 22 is ejected in droplets and falls. The phosphor-containing resin 14 in the form of droplets falls toward and is dot-printed on the base substrate 11 and/or the LED chip 12.

In the present embodiment, since the droplets of the phosphor-containing resin 14 are dot-printed on the base substrate 11 and/or the LED chip 12 by inkjet printing, a resin having a higher viscosity (e.g., not less than 5 Pa·s) than a resin used for typical potting can be used for the phosphor-containing resin 14. That is, the phosphor-containing resin 14 in the liquid form before curing as well as in the droplet form may have a viscosity of not less than 5 Pa·s. When the phosphor-containing resin 14 has high viscosity, deposition of phosphor contained in the phosphor-containing resin 14 is less likely to occur in the inkjet head 20. Therefore, variation in the phosphor concentration in the dripped droplet is reduced and it is thus possible to suppress color unevenness among devices when plural light-emitting devices 10 are formed.

The structure of the light-emitting device 10 is not limited to COB. It is also possible to form the phosphor-containing resin 14 by inkjet dot printing in, e.g., a package in which the LED chip 12 is mounted on a lead frame.

Following is the result of evaluating heat release characteristics of the light-emitting device 10 in the present embodiment. As an example, heat release characteristics in case of forming the phosphor-containing resin 14 of the light-emitting device 10 in the present embodiment by inkjet dot printing as described above and heat release characteristics in case of forming the phosphor-containing resin 14 by typical potting without using inkjet printing were evaluated. The comparison result is shown below.

For this evaluation, an AlN substrate was used as the base substrate 11, a blue LED was used as the LED chip 12, and a silicone resin containing a YAG phosphor which is a yellow phosphor was used as the phosphor-containing resin 14.

Firstly, the phosphor-containing resin 14 having a thickness of 60 μm (thickness from the upper surface of the LED chip 12 to the upper surface of the phosphor-containing resin 14) was formed in one light-emitting device 10 (hereinafter, referred to as “light-emitting device A”) by inkjet dot printing. The protective resin 15 was then formed.

Next, the phosphor-containing resin 14 was formed in another light-emitting device 10 (hereinafter, referred to as “light-emitting device B”) by typical potting so as to have a thickness which allows light with the same chromaticity as the light-emitting device A to be emitted. In case of typical potting, the phosphor concentration of the phosphor-containing resin 14 cannot be increased to as high as that for inkjet dot printing. Therefore, the thickness of the phosphor-containing resin 14 was 200 μm. The protective resin 15 was not subsequently formed.

Temperature rise from substrate temperature (the temperature of the base substrate 11) during light emission was measured on the obtained light-emitting devices A and B. The maximum rise was 42.5° C. in the light-emitting device A and 102.6° C. in the light-emitting device B. That is, the maximum temperature rise from substrate temperature in the light-emitting device A was 60° C. lower than that in the light-emitting device B.

### Effects of the Embodiment

In the embodiment, it is possible to form the phosphor-containing resin 14 containing a phosphor at a high concentration and having excellent thermal conductivity by inkjet dot printing. This allows heat generated due to Stokes shift during fluorescence emission to be efficiently released to the outside. Therefore, it is possible to suppress cracks or change in properties of the phosphor-containing resin 14 and reliability is thereby improved.

Although the embodiment of the invention has been described, the invention is not intended to be limited to the embodiment and the various kinds of modifications can be implemented without departing from the gist of the invention.

In addition, the invention according to claims is not to be limited to the above-mentioned embodiment. Further, all combinations of the features described in the embodiment are not needed to solve the problem of the invention.

What is claimed is:

1. A method of manufacturing a light-emitting device, comprising:
providing an LED chip mounted on a base substrate; and
dripping a droplet of a phosphor-containing resin to cover the LED chip,
wherein the droplet is dot-printed on the base substrate and/or the LED chip by inkjet printing.

2. The method according to claim 1, wherein a concentration of a phosphor included in the phosphor-containing resin is not less than 20 vol %.

3. The method according to claim 1, wherein the droplet has a viscosity of not less than 5 Pa·s.
